(19) United States
(12) Patent Application Publication
(10) Pub. No.: US 2020/0243556 A1
(43) Pub. Date: Jul. 30, 2020

(54) THREE-DIMENSIONAL STACKED SEMICONDUCTOR DEVICE AND METHOD OF MANUFACTURING THE SAME

(71) Applicant: MACRONIX INTERNATIONAL CO., LTD., Hsinchu (TW)

(72) Inventor: Guan-Ru LEE, Kaohsiung City (TW)

(21) Appl. No.: 16/257,176

(22) Filed: Jan. 25, 2019

(51) Int. Cl. H01L 27/11582; H01L 21/28

(52) U.S. Cl. CPC H01L 27/11582; H01L 21/28282

(57) ABSTRACT

A three-dimensional stacked semiconductor device includes a patterned multi-layered stacks formed in an array area of a substrate, wherein one of the patterned multi-layered stacks includes insulating layers and conductive layers arranged alternately, and a top gate layer is disposed above the conductive layers; a vertical channel structure disposed between the patterned multi-layered stacks and comprising a tunneling layer on the patterned multi-layered stacks and a channeling layer on the tunneling layer, wherein lateral sides of the top gate layer of one patterned multi-layered stack directly contact the tunneling layer; and discrete confined structures formed in recess regions adjacent to sidewalls of the conductive layers of the patterned multi-layered stacks, wherein one discrete confined structure includes a blocking layer formed as a liner in the recess region and a charge chapping element in contact with the blocking layer and the tunneling layer.

### BACKGROUND

### Field of the Invention

The disclosure relates in general to a three-dimensional (3D) stacked semiconductor device and a method of manufacturing the same, and more particularly to a 3D stacked device having uniform surfaces of data storage structures and a method of manufacturing the same.

### Description of the Related Art

A nonvolatile semiconductor memory device is typically designed to securely hold data even when power is lost or removed from the memory device. Various types of nonvolatile memory devices have been proposed in the related art. Also, manufactures have been looking for new developments or techniques combination for stacking multiple planes of memory cells, so as to achieve greater storage capacity. For example, several types of multi-layer stackable

NAND-type flash memory device s have been proposed. However, the typical 3D stacked semiconductor device still suffers from some problems.

For example, for a 3D NAND architecture of semiconductor device, retention is a critical issue due to non-cut charge trapping layer (such as nitride), especially in a direction along which several conductive layers and insulating layers are stacked alternately. According to the conventional method of manufacturing a 3D stacked device, poly pull-back is a common approach to obtain confined structures. However, it has drawbacks that non-uniformed amounts of the recessed regions for forming the confined structures would be occurred, which lead to the waving surfaces of the sidewalls of the confined structures and the charge chapping layer, thereby affecting the electrical performance of the 3D stacked semiconductor device.

### SUMMARY

The disclosure relates to a three-dimensional (3D) stacked semiconductor device and a method of manufacturing the same. According to the embodiment, the manufacturing method provides a device including components having uniform surfaces, thereby improving the reliability of electrical performance of the 3D stacked semiconductor device as manufactured.

According to one embodiment of the present disclosure, a 3D stacked semiconductor device is provided, comprising: a substrate, having an array area and a staircase area; patterned multi-layered stacks formed in the array area and above the substrate, and the patterned multi-layered stacks spaced apart from each other, wherein one of the patterned multi-layered stacks comprises insulating layers and conductive layers arranged alternately, and a top gate layer is disposed above the conductive layers; a vertical channel structure, disposed between the patterned multi-layered stacks, and the vertical channel structure comprising a tunneling layer disposed on the patterned multi-layered stacks and a channeling layer formed on the tunneling layer, wherein lateral sides of the top gate layer of said one of the patterned multi-layered stacks directly contact the tunneling layer; and discrete confined structures, formed in recess regions adjacent to sidewalls of the conductive layers of the patterned multi-layered stacks, and each of the discrete confined structures comprising a blocking layer formed as a liner in the recess region and a charge chapping element in contact with the blocking layer and the tunneling layer.

According to one embodiment of the present disclosure, a method of manufacturing a 3D stacked semiconductor device is provided, comprising: forming patterned multi-layered stacks above a substrate and within an array region of the substrate, wherein the patterned multi-layered stacks are spaced apart from each other, and channel holes are formed between the patterned multi-layered stacks disposed adjacently, and one of the patterned multi-layered stacks comprising insulating layers and conductive layers are arranged alternately; forming a top gate layer disposed above the conductive layers of said one of the patterned multi-layered stacks and forming discrete confined structures in recess regions adjacent to sidewalls of the conductive layers of the patterned multi-layered stacks, wherein each of the discrete confined structures comprises a blocking layer formed as a liner in the recess region and a charge chapping element in contact with the blocking layer; and forming a vertical channel structure on the patterned multi-layered stacks, wherein the vertical channel structure comprises a tunneling layer disposed on the patterned multi-layered stacks and a channeling layer formed on the tunneling layer, wherein lateral sides of the top gate layer of said one of the patterned multi-layered stacks directly contact the tunneling layer.

The disclosure will become apparent from the following detailed description of the preferred but non-limiting embodiments. The following description is made with reference to the accompanying drawings.

### BRIEF DESCRIPTION OF THE DRAWINGS

FIG. 1A-FIG. 11 illustrate a method of manufacturing a three-dimensional (3D) stacked semiconductor device according to an embodiment of the present disclosure.

FIG. 2 depicts a three-dimensional (3D) stacked semiconductor device according to one embodiment of the disclosure.

### DETAILED DESCRIPTION

In the embodiments of the present disclosure, a three-dimensional (3D) stacked semiconductor device and a method of manufacturing the same are provided. According to the manufacturing method of the embodiment, the data storage structures of a 3D stacked semiconductor device, such as including the blocking layers, the charge chapping elements and the tunneling layer, with uniform surfaces can be obtained, to solve the waving-surface problem of the data storage structures generally occurred in the conventional 3D stacked semiconductor device. In one embodiment, a charge chapping film is deposited for filling regions between patterned multi-layered stacks before forming a top conductive film (for forming top select gates in subsequent procedure), and then additional removing process (such as etching process) is performed to isolate the charge chapping elements and create confined structures in recessed regions adjacent to sidewalls of the conductive layers of the patterned multi-layered stacks. Accordingly, no confined structure is formed adjacent to lateral sides of the top gate layers. The manufacturing method provides a device including components having uniform surfaces, thereby improving the reliability of electrical performance of the 3D stacked semiconductor device as manufactured. Moreover, the method of the embodiment causes no damage to the related layers and components of the device, and the method of the embodiment is also suitable for manufacturing the 3D stacked semiconductor device with large number of the stacking layers without affecting the configuration of device of the embodiment.

The embodiment of the present disclosure could be implemented in many different 3D stacked semiconductor devices in the applications. For example, the embodiment could be applied to, but not limited to, the 3D vertical-channel (VC) semiconductor devices. The embodiment is provided hereinafter with reference to the accompanying drawings for elaborating one of the 3D stacked semiconductor devices and a method of manufacturing the same. However, the present disclosure is not limited thereto. The descriptions disclosed in the embodiments of the disclosure such as detailed configurations, manufacturing procedures and material selections are for illustration only, not for limiting the scope of protection of the disclosure.

Also, it is noted that not all embodiments of the invention are shown. Modifications and variations can be made without departing from the spirit of the disclosure to meet the requirements of the practical applications. Thus, there may be other embodiments of the present disclosure which are not specifically illustrated. It is also important to point out that the illustrations may not be necessarily be drawn to scale. Thus, the specification and the drawings are to be regard as an illustrative sense rather than a restrictive sense.

Moreover, use of ordinal terms such as “first”, “second”, “third” etc., in the specification and claims to describe an element does not by itself connote any priority, precedence, or order of one claim element over another or the temporal order in which acts of a method are performed, but are used merely as labels to distinguish one claim element having a certain name from another element having the same name (but for use of the ordinal term) to distinguish the claim elements.

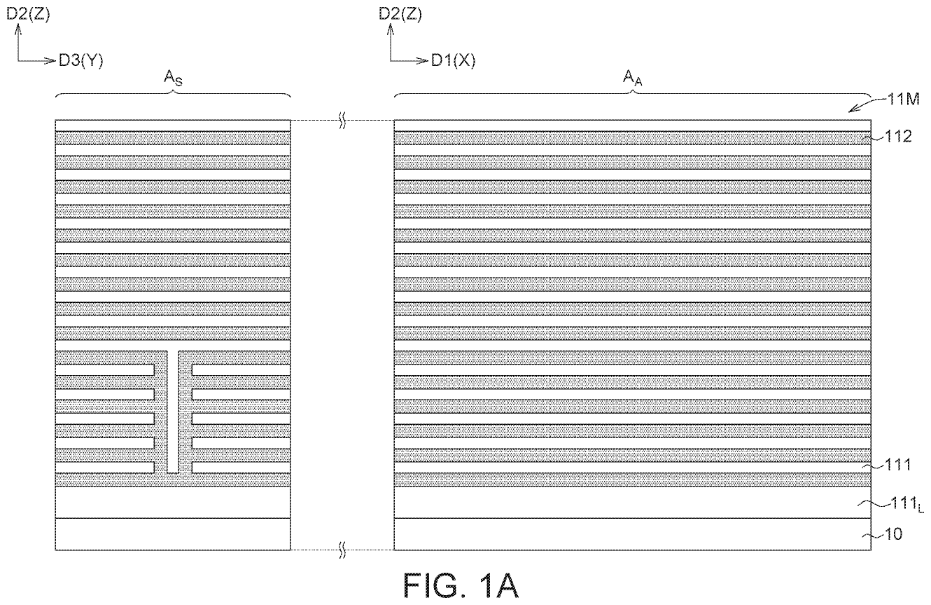

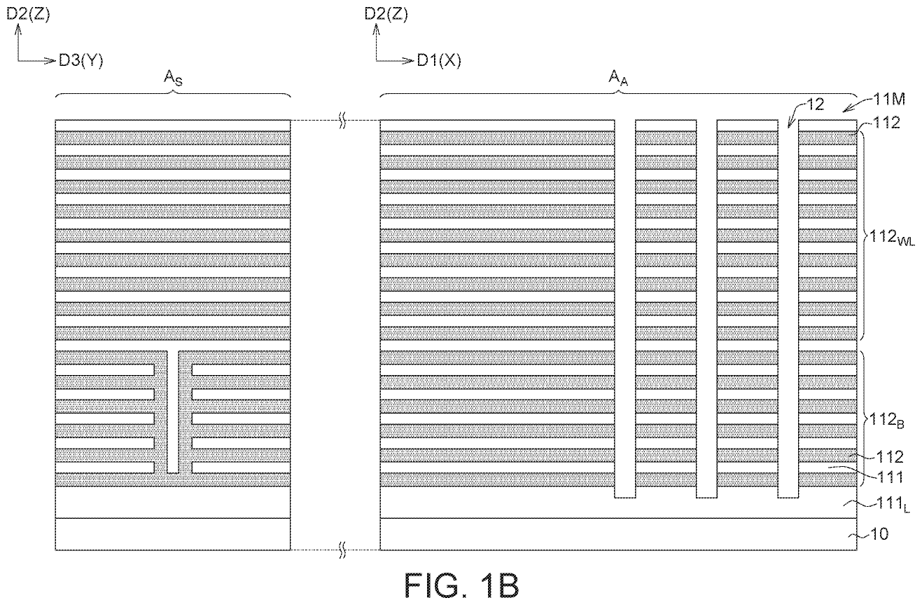

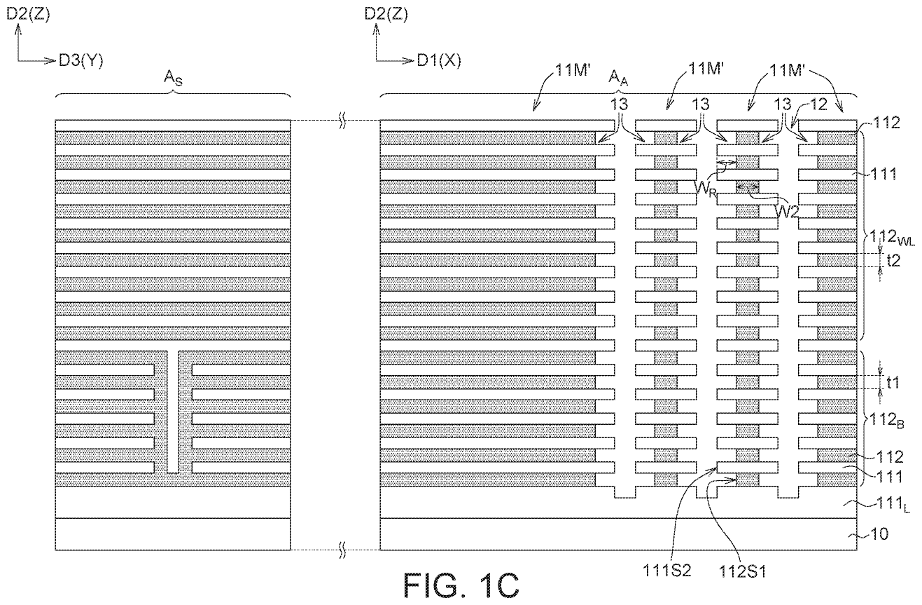

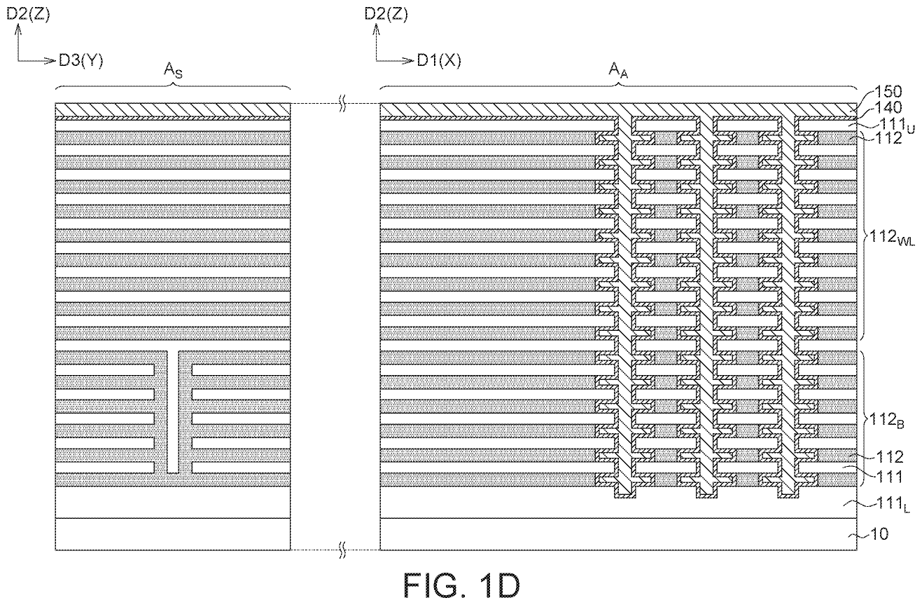

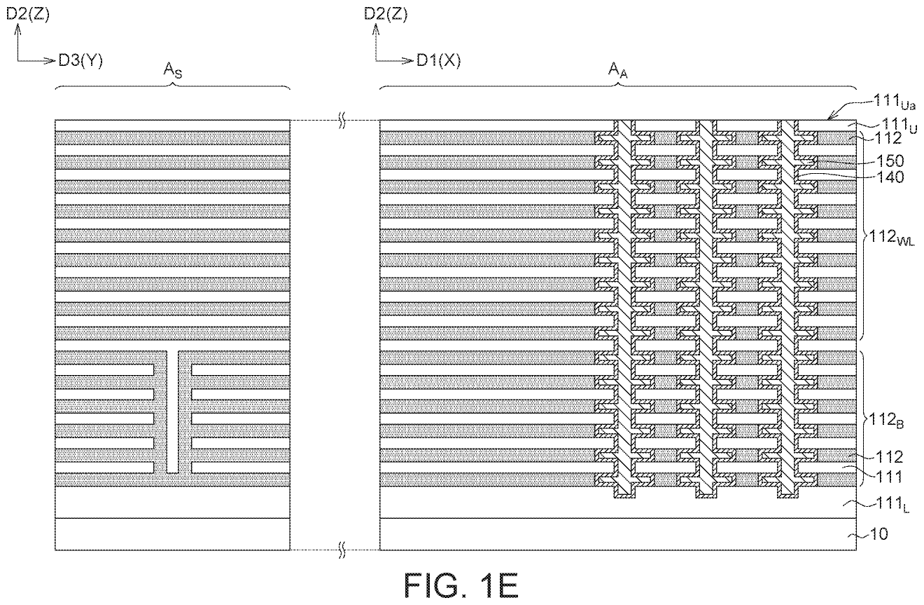

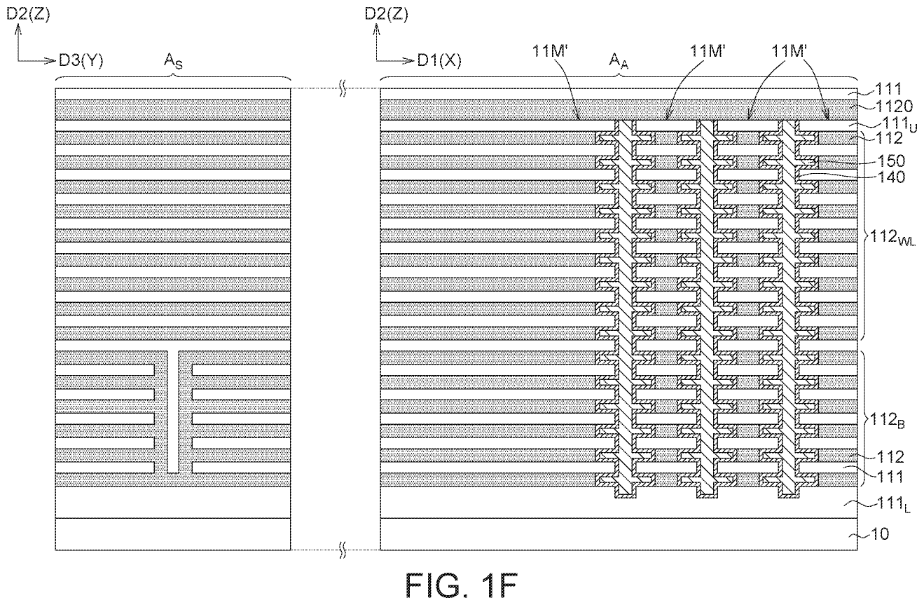

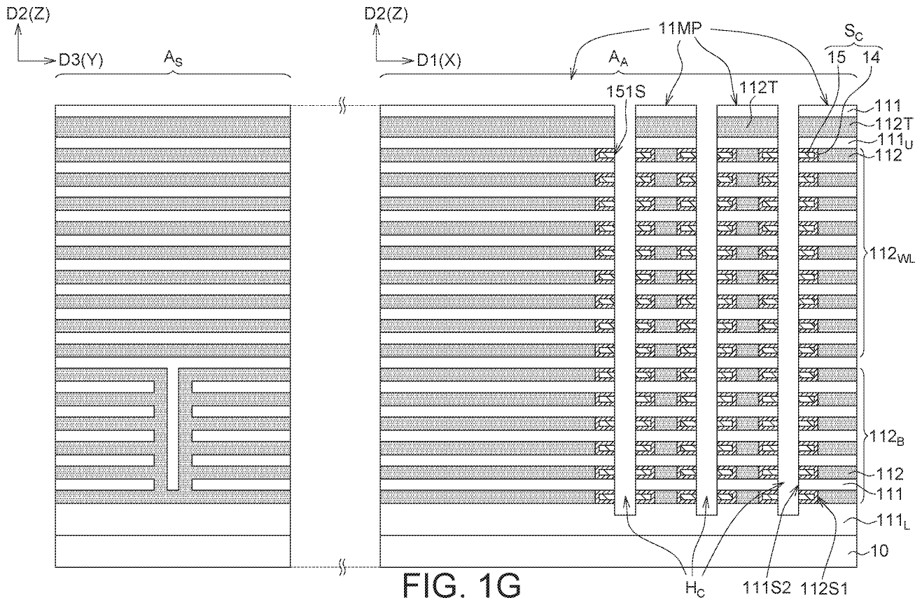

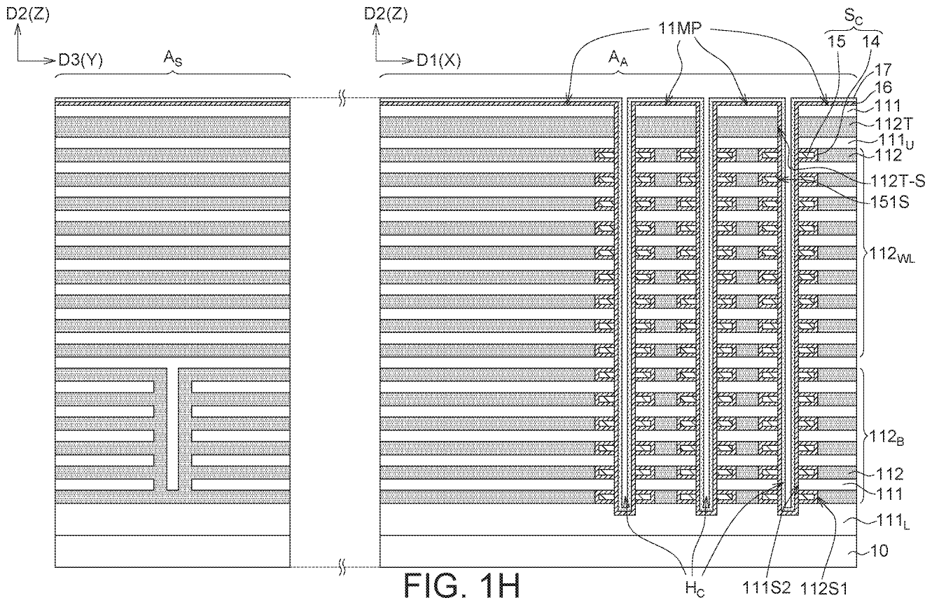

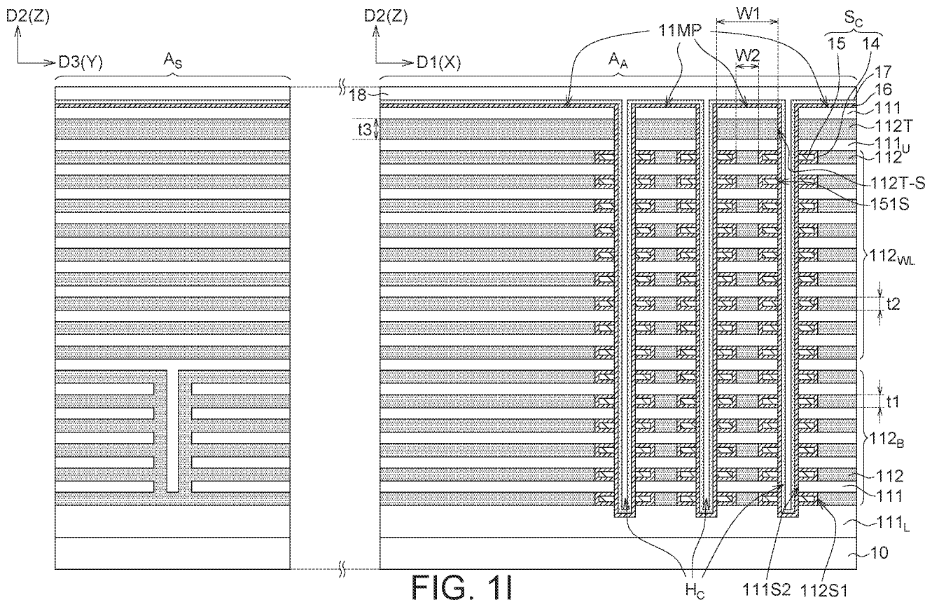

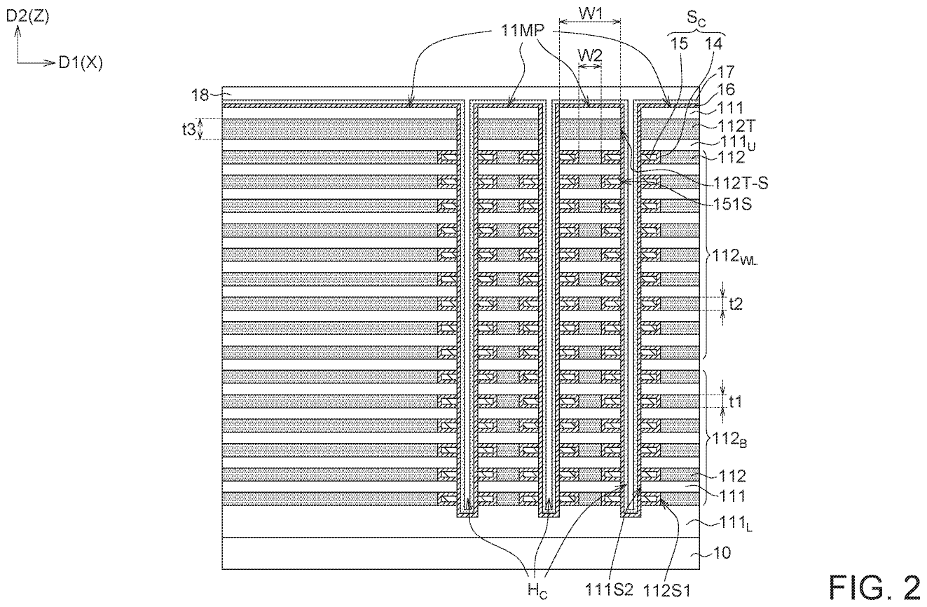

FIG. 1A-FIG. 11 illustrate a method of manufacturing a 3D stacked semiconductor device according to an embodiment of the present disclosure. As shown in FIG. 1A, a multi-layered stack 11M is formed above a substrate 10 having an array area A_{A} and a staircase area A_{S}, and the multi-layered stack 11M comprises a plurality of insulating layers 111 and a plurality of conductive layers 112 arranged alternately along a second direction D2 (ex: Z-direction) vertical to the substrate 10. In one embodiment, the insulating layers 111 could be oxide layers, and the conductive layers 112 could be polysilicon layers (ex: heavily doped N+ polysilicon layers or heavily doped P+ polysilicon layers).

In one exemplified (but not limited) example, the conductive layers of the multi-layered stack 11M in the array region A_{A} of the substrate 10 comprises a plurality of first conductive layers 112B and plurality of second conductive layers 112_{WL}. In one example, the first conductive layers 112_{B} are formed above the substrate 10 and function as a bottom gate layer; and the second conductive layers 112_{WL} formed above the first conductive layers 112_{B} and function as word lines of the device.

Then, the multi-layered stack 11M is patterned, such as by etching, to form several holes 12, as shown in FIG. 1B. In one example, the holes 12 extend downwardly to penetrate the second conductive layers 112_{WL} and the first conductive layers 112_{B} and expose a lowest insulating layer 111_{L} (such as a buried oxide layer formed on the substrate 10).

As shown in FIG. 1C, the conductive layers 112, including the first conductive layers 112_{B} and the second conductive layers 112_{WL}, are recessed relative to the insulating layers 111, so as to form the stacked pillars 11M′ extended vertically on the substrate 10. Therefore, the recess regions 13 are formed adjacent to the sidewalls of the conductive layers 112 of the stacked pillars 11M′. In one embodiment, the conductive layers 112 have the first sidewalls 112S1 and the insulating layers 111 have the second sidewalls 111S2, wherein the first sidewalls 112S1 of the conductive layers 112 are recessed relative to the second sidewalls 111S2 of the insulating layers 111 to define the recess regions 13.

Additionally, extension of the recess regions 13 can be determined and modified according to actual needs of the practical requirements. In one example, the recess regions 13 have a width W_{R} parallel to a first direction D1 (such as X-direction in FIG. 1C), wherein the width W_{R} can be smaller than or substantially equal to the width (e.g. the second width W2 in FIG. 11) of the remained portions of the conductive layers 112 after recessing step; however, the disclosure has no limitation thereto. Furthermore, one of the first conductive layers 112_{B} has a first thickness t1 (along the second direction D2; e.g. Z-direction), one of the second conductive layers 112_{WL} has a second thickness t2; in one example, the first thickness t1 can be substantially identical to the second thickness t2, but the disclosure is not limited thereto.

Afterwards, a blocking film 140 is deposited to form blocking liners in the recess regions 13, and a charge chapping film 150 is deposited on the blocking film 140, wherein the charge chapping film 150 fully fills the spaces between the stacked pillars 11M′, such as the spaces between opposite liner portions of the blocking film 140 at the stacked pillars 11M′, as shown in FIG. 1D. Also, the blocking film 140 and the charge chapping film 150 above cover the uppermost insulating layer 111_{U}.

The blocking film 140 can include a combination of multilayer thin films to optimize erase saturation. For example, the combination of multilayer thin films can include layers of materials such as High-κ (high dielectric constant as compared to silicon dioxide) dielectric material, capped SiN, ONO (Oxide-Nitride-Oxide) for double trapping BE-SONOS (Band-gap Engineered Silicon-Oxide-Nitride-Oxide-Silicon). In one example, the charge chapping film 150 typically includes SiN (silicon nitride). In other examples, the charge chapping film 150 can include SiON, HfO₂, Al₂O₃, etc. In the exemplified drawings of the embodiment, one integrated layer is depicted as the charge chapping film 150 for clear illustration.

Then, the charge chapping film 150 is etched back to expose the top surface 111_{Ua}, of the uppermost insulating layer 111_{U}, as shown in FIG. 1E. As shown in FIG. 1F, a top conductive film 1120 is formed on the charge chapping film 150, the blocking film 140 and the stacked pillars 11M′. Also, another insulating layer 111 is deposited to cover the top conductive film 1120.

Afterwards, as shown in FIG. 1G, the channel holes H_{C} are formed by removing parts of the top conductive film 1120, a portion of the charge chapping film 150 between the stacked pillars and parts of the blocking film 140 to expose the sidewalls (i.e. the second sidewalls 111S2) of the insulating layers 111, wherein the channel holes H_{C} are extended vertically along the second direction D2 (e.g. Z-direction) and also vertical to an extending plane of the substrate 10. Thus, several patterned multi-layered stacks 11MP are formed on the substrate 10 consequently.

Please refer to FIG. 1F and FIG. 1G, according to one embodiment, the parts of the top conductive film 1120, the portion of the charge chapping film 150 between the stacked pillars and the parts of the blocking film 140 within the array area A_{A} of the substrate 10 can be removed by one-step procedure, such as one-step etching to cut through related layers, thereby forming the top gate layers 112T above the conductive layers 112 and forming the discrete confined structures S_{C} in the recess regions 13 adjacent to the sidewalls of the conductive layers 112 of the patterned multi-layered stacks 11MP. Also, the channel holes H_{C} as formed expose the lowest insulating layer 111_{L} (such as a buried oxide layer formed on the substrate 10). In one example, the top conductive film 1120 as shown in FIG. 1F extends along the first direction D1 (e.g. X-direction) of the extending plane of the substrate 10, and the etching is performed by cutting the related material layers along the second direction D2 (e.g. Z-direction) as shown in FIG. 1G, wherein the second direction D2 is perpendicular to the first direction D1. According to the embodiment, the patterned multi-layered stacks 11MP have uniformed profiles, and no waving lateral surface of related elements (e.g. the top gate layers 112T, the conductive layers 112 and the insulating layers 111) of the patterned multi-layered stacks 11MP would be created.

Additionally, after one-step etching procedure, the discrete confined structures S_{C} in the recess regions 13 are formed, as shown in FIG. 1G, wherein the discrete confined structures S_{C} are isolated from each other by the insulating layers 111 therebeween. In one example, a discrete confined structure S_{C} comprises a blocking layer 14 formed as a liner in the recess region 13 and a charge chapping element 15 in the region between the blocking layer 14, wherein the charge chapping element 15 is in contact with the blocking layer 14.

After forming the channel holes H_{C}, a tunneling layer 16 is deposited on the patterned multi-layered stacks 11MP and covers the patterned multi-layered stacks 11MP, as shown in FIG. 1H. The tunneling layer 16 is deposited along the sidewalls of the patterned multi-layered stacks 11MP. Then, a channeling layer 17 is deposited over the tunneling layer 16. In FIG. 1H, the top gate layer 112T of each of the patterned multi-layered stacks 11MP is embedded in the tunneling layer 16. According to the embodiment, the tunneling layer 16 directly contacts the lateral sides 112T-S of the top gate layers 112T of the patterned multi-layered stacks 11MP. In FIG. 1H, for example, two lateral sides 112T-S of the top gate layer 112T positioned oppositely are entirely contacted and covered by the tunneling layer 16. Also, in the embodiment, the tunneling layer 16 directly contacts the sidewalls (i.e. the second sidewalls 111S2) of the insulating layers 111 of the patterned multi-layered stacks 11MP, and directly contacts the discrete confined structures S_{C}; for example, the tunneling layer 16 directly contacts lateral sides 151S of the charge chapping elements 15.

In one embodiment, the tunneling layer 16 can include a bandgap engineered composite tunneling dielectric layer comprising a layer of silicon dioxide. In one (but not limited) example, the composite tunneling dielectric layer consists of an ultrathin silicon oxide layer, an ultrathin silicon nitride layer and an ultrathin silicon oxide layer. Also, In one example, the channeling layer 17 includes polysilicon.

Afterwards, a dielectric layer 18 is deposited on the patterned multi-layered stacks 11MP and fills remained spaces between adjacent patterned multi-layered stacks 11MP, as shown in FIG. 1I. In one example, the dielectric layer 18 contacts the channeling layer 17 formed between the adjacent patterned multi-layered stacks 11MP. In one example, the dielectric layer 18 may include oxide.

FIG. 2 depicts a three-dimensional (3D) stacked semiconductor device according to one embodiment of the disclosure. FIG. 2 merely shows a configuration of a 3D stacked semiconductor device within an array area A_{A} of the substrate 10 for clearly illustration. In FIG. 2, several patterned multi-layered stacks 11MP in the array area A_{A} are formed above the substrate 10, and the patterned multi-layered stacks 11MP are spaced apart from each other. One of the patterned multi-layered stacks 11MP comprises several insulating layers 111 and several conductive layers 112 arranged alternately, and a top gate layer 112T is disposed above the conductive layers 112. Also, a vertical channel structure is disposed between the patterned multi-layered stacks 11MP, wherein the vertical channel structure comprises the tunneling layer 16 disposed on the patterned multi-layered stacks 11MP and the channeling layer 17 formed on the tunneling layer 16. In the embodiment, the lateral sides 112T-S of the top gate layer 112T of one of the patterned multi-layered stacks 11MP directly contact the tunneling layer 16. Also, in the 3D stacked semiconductor device of the embodiment, the discrete confined structures S_{C} are formed in the recess regions 13 adjacent to the sidewalls (i.e. the first sidewalls 112S1) of the conductive layers 112 of the patterned multi-layered stacks 11MP, and each of the discrete confined structures S_{C} comprises a blocking layer 14 formed as a liner in the recess region 13 and a charge chapping element 15 in contact with the blocking layer 14 and the tunneling layer 16. In one example, the data storage structures of an embodied 3D stacked semiconductor device include the blocking layers 14, the charge chapping elements 15 and the tunneling layer 16.

In FIG. 2, the blocking layer 14 can be regarded as being formed between adjacent two of the insulating layers 111. Also, the charge chapping elements 15 of the discrete confined structures S_{C} are discretely disposed along the second direction D2 (e.g. Z direction). According to the manufacturing method of the embodiment, the top gate layers 112T of the patterned multi-layered stacks 11MP and the discrete confined structures S_{C} are formed simultaneously; for example, formed by the same etching step, as illustrated in FIG. 1G. Thus, the lateral sides 112T-S of the top gate layers 112T of the patterned multi-layered stacks 11MP are substantially aligned with lateral sides 151S of the charge chapping elements 15.

Additionally, according to the device manufactured by the embodied method, the top gate layer 112T of one of the patterned multi-layered stacks 11MP has a first width W1 parallel to the first direction D1 (e.g. X-direction), and one of the conductive layers 112 of the patterned multi-layered stacks 11MP (stacked along the second direction D2 (e.g. Z-direction)) has a second width W2 parallel to the first direction D1 (e.g. X-direction), wherein the first width W1 is larger than the second width W2. Furthermore, in one exemplified (but not limited) example for the configurations of the conductive layers 112 and the top gate layers 112T, one of the first conductive layers 112B has a first thickness t1 (along the second direction D2; e.g. Z-direction), one of the second conductive layers 112_{WL} has a second thickness t2 (along the second direction D2), wherein the first thickness t1 is substantially identical to the second thickness t2, and the first thickness t1/the second thickness t2 is smaller than a thickness t3 (along the second direction D2) of the top gate layer 112T.

According to the stacked semiconductor device and manufacturing method as illustrated in the embodiment above, a charge chapping film is deposited for filling regions between patterned multi-layered stacks before forming a top conductive film (for forming top select gates in subsequent procedure), and then additional removing process (such as etching process) is performed to isolate the charge chapping elements and create confined structures in recessed regions adjacent to sidewalls of the conductive layers of the patterned multi-layered stacks. Accordingly, no confined structure is formed adjacent to lateral sides of the top gate layers. According to the method of manufacturing an embodied stacked semiconductor device, the data storage structures of the embodied 3D stacked semiconductor device, such as including the blocking layers 14, the charge chapping elements 15 and the tunneling layer 16 (in FIG. 2) having uniform surfaces can be obtained, to solve the waving-surface problem of the data storage structures generally occurred in the conventional 3D stacked semiconductor device. Thus, the manufacturing method provides a device including components having uniform surfaces, thereby improving the reliability of electrical performance of the 3D stacked semiconductor device as manufactured. Moreover, the method of the embodiment causes no damage to the related layers and components of the device, and the method of the embodiment is also suitable for manufacturing the 3D stacked semiconductor device with large number of the stacking layers without affecting the configuration of device of the embodiment (i.e. structure possesses a solid construction, a complete profile of the related layers and components). Furthermore, the 3D stacked semiconductor device of the embodiment is manufactured by adopting no time-consuming and expensive procedures, which is suitable for mass production.

It is noted that the structures and methods as described above are provided for illustration. The disclosure is not limited to the configurations and procedures disclosed above. Other embodiments with different configurations of known elements can be applicable, and the exemplified structures could be adjusted and changed based on the actual needs of the practical applications. It is, of course, noted that the configurations of figures are depicted only for demonstration, not for limitation. Thus, it is known by people skilled in the art that the related elements and layers in the array area of a 3D stacked semiconductor device, the shapes or positional relationship of the elements and the procedure details could be adjusted or changed according to the actual requirements and/or manufacturing steps of the practical applications.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A three-dimensional (3D) stacked semiconductor device, comprising:
a substrate, having an array area and a staircase area;
patterned multi-layered stacks formed in the array area and above the substrate, and the patterned multi-layered stacks spaced apart from each other, wherein one of the patterned multi-layered stacks comprises insulating layers and conductive layers arranged alternately, and a top gate layer is disposed above the conductive layers;
a vertical channel structure, disposed between the patterned multi-layered stacks, and the vertical channel structure comprising a tunneling layer disposed on the patterned multi-layered stacks and a channeling layer formed on the tunneling layer, wherein lateral sides of the top gate layer of said one of the patterned multi-layered stacks directly contact the tunneling layer; and
discrete confined structures, formed in recess regions adjacent to sidewalls of the conductive layers of the patterned multi-layered stacks, and each of the discrete confined structures comprising a blocking layer formed as a liner in the recess region and a charge chapping element in contact with the blocking layer and the tunneling layer.

2. The 3D stacked semiconductor device according to claim 1, wherein the conductive layers and the insulating layers of the patterned multi-layered stacks respectively have first sidewalls and second sidewalls, and the first sidewalls are recessed relative to the second sidewalls to define the recess regions.

3. The 3D stacked semiconductor device according to claim 1, wherein the tunneling layer directly contacts sidewalls of the insulating layers of the patterned multi-layered stacks.

4. The 3D stacked semiconductor device according to claim 1, wherein the lateral sides of the top gate layers of the patterned multi-layered stacks are substantially aligned with lateral sides of the charge chapping elements.

5. The 3D stacked semiconductor device according to claim 1, wherein a first width of the top gate layer of said one of the patterned multi-layered stacks is parallel to a first direction, and the conductive layers of the patterned multi-layered stacks are stacked along a second direction, wherein the second direction is perpendicular to the first direction.

6. The 3D stacked semiconductor device according to claim 5, wherein a second width of the conductive layers of said one of the patterned multi-layered stacks is parallel to the first direction, and the first width is larger than the second width.

7. The 3D stacked semiconductor device according to claim 1, wherein the conductive layers of said one of the patterned multi-layered stacks comprises:
a plurality of first conductive layers, formed above the substrate and functioning as a bottom gate layer; and
a plurality of second conductive layers formed above the plurality of first conductive layers,
wherein one of the plurality of first conductive layers has a first thickness, one of the plurality of second conductive layers has a second thickness, and the first thickness is substantially identical to the second thickness.

8. The 3D stacked semiconductor device according to claim 7, wherein the first thickness is smaller than a thickness of the top gate layer.

9. A method of manufacturing a three-dimensional (3D) stacked semiconductor structure, comprising:
forming patterned multi-layered stacks above a substrate and within an array region of the substrate, wherein the patterned multi-layered stacks are spaced apart from each other, and channel holes are formed between the patterned multi-layered stacks disposed adjacently, and one of the patterned multi-layered stacks comprising insulating layers and conductive layers are arranged alternately;
forming a top gate layer disposed above the conductive layers of said one of the patterned multi-layered stacks and forming discrete confined structures in recess regions adjacent to sidewalls of the conductive layers of the patterned multi-layered stacks, wherein each of the discrete confined structures comprises a blocking layer formed as a liner in the recess region and a charge chapping element in contact with the blocking layer; and
forming a vertical channel structure on the patterned multi-layered stacks, wherein the vertical channel structure comprises a tunneling layer disposed on the patterned multi-layered stacks and a channeling layer formed on the tunneling layer,
wherein lateral sides of the top gate layer of said one of the patterned multi-layered stacks directly contact the tunneling layer.

10. The method according to claim 9, wherein the conductive layers and the insulating layers of the patterned multi-layered stacks respectively have first sidewalls and second sidewalls, and the first sidewalls are recessed relative to the second sidewalls to define the recess regions.

11. The method according to claim 9, wherein the tunneling layer directly contacts sidewalls of the insulating layers of the patterned multi-layered stacks.

12. The method according to claim 9, wherein the lateral sides of the top gate layers of the patterned multi-layered stacks are substantially aligned with lateral sides of the charge chapping elements.

13. The method according to claim 9, wherein a first width (W1) of the top gate layer of said one of the patterned multi-layered stacks is parallel to a first direction, and the conductive layers of the patterned multi-layered stacks are stacked along a second direction, wherein the second direction is perpendicular to the first direction.

14. The method according to claim 13, wherein a second width of the conductive layers of said one of the patterned multi-layered stacks is parallel to the first direction, and the first width is larger than the second width.

15. The method according to claim 9, wherein the conductive layers of said one of the patterned multi-layered stacks comprises:
a plurality of first conductive layers, formed above the substrate and functioning as a bottom gate layer; and
a plurality of second conductive layers formed above the plurality of first conductive layers,
wherein one of the plurality of first conductive layers has a first thickness, one of the plurality of second conductive layers has a second thickness, and the first thickness is substantially identical to the second thickness.

16. The method according to claim 9, wherein the top gate layers of the patterned multi-layered stacks and the discrete confined structures are formed simultaneously.

17. The method according to claim 9, wherein step of forming patterned multi-layered stacks above the substrate comprises:
forming the insulating layers and the conductive layers arranged alternately on the substrate;
recessing the conductive layers relative to the insulating layers so as to form stacked pillars on the substrate and the recess regions adjacent to the sidewalls of the conductive layers of the stacked pillars;
depositing a blocking film to form blocking liners in the recess regions;
depositing a charge chapping film on the blocking film, and the charge chapping film fully filling spaces between the stacked pillars;
forming a top conductive film on the charge chapping film, the blocking film and the stacked pillars; and
forming the channel holes by removing parts of the top conductive film, a portion of the charge chapping film between the stacked pillars and parts of the blocking film to expose sidewalls of the insulating layers, wherein the channel holes are extended vertically to an extending plane of the substrate.

18. The method according to claim 17, wherein the parts of the top conductive film, the portion of the charge chapping film between the stacked pillars and the parts of the blocking film are removed by one-step etching, thereby forming the top gate layers above the conductive layers and forming the discrete confined structures in the recess regions adjacent to the sidewalls of the conductive layers of the patterned multi-layered stacks.

19. The method according to claim 17, wherein after forming the channel holes, the tunneling layer is formed on the patterned multi-layered stacks to directly contact the lateral sides of the top gate layers of the patterned multi-layered stacks.

20. The method according to claim 9, further comprising depositing a dielectric layer on the patterned multi-layered stacks and the dielectric layer filling remained spaces between adjacent patterned multi-layered stacks.
